(19) United States
(12) Patent Application Publication
(10) Pub. No.: US 2010/0188806 A1
(43) Pub. Date: Jul. 29, 2010

(54) CONFIGURABLE ELECTRONIC DEVICE

(76) Inventor: Andrew Mulford, Edinburgh Lotthian (GB)

Correspondence Address: JENKINS, WILSON, TAYLOR & HUNT, P. A., Suite 1200 UNIVERSITY TOWER, 3100 TOWER BLVD.,, DURHAM, NC, 27707, US

(21) Appl. No.: 12/598,345

(22) PCT Filed: Apr. 30, 2008
(86) PCT No.: PCT/GB08/50311

§ 371 Date: Mar. 19, 2010

(30) Foreign Application Priority Data
May 1, 2007 (GB) 0708432.0

(51) Int. Cl. H05K 7/00

(52) U.S. Cl. 361/679.01

(57) ABSTRACT

Configurable electronic devices are presented. In particular, two, three and four sections devices are presented that permit a single devices to take on a plurality of configurations so as to provide the functionality of a range of known mobile electronic devices e.g. a notebook computer, a mobile telephone, a palm top computer, a communicator, a personal digital assistant (PDA), an electronic organiser, a games console, a remote control, and the like. An arm or wrist mount may also be incorporated which allows the device to be attached to the arm or wrist of a user with only minimal impact upon their manual dexterity.

The present invention relates to a configurable electronic device. In particular, the invention relates to an electronic device that can be configured so as to provide the functionality of a range of known mobile electronic devices e.g. a notebook computer, a mobile telephone, a palm top computer, a communicator, a personal digital assistant (PDAs), an electronic organiser, a games console, a remote control, and the like.

Mobile electronic devices are being manufactured with increasing capability. Many devices now incorporate multiple functions, (such as a mobile telephone, a palm top computer and a games player) into a single device. These technologies often require differing form factors to optimize their usability.

Within the medical field, and in particular mobile medical units, there has been an increasing employment of mobile electronic devices so as to assist in the monitoring, diagnosis and recording of a patient condition. Such devices have found particular application with emergency response units wherein a quick diagnosis of a patient's condition can be critical in saving their life and in reducing recovery times. For example, the early recordal and relay of accurate information about a patient's condition in the field allows for medical facilities to make appropriate preparations in advance of the arrival of the patient. As will be readily apparent, this is of significant benefit for the treatment of the patient.

Those mobile electronic devices known in the art are limited in their configurability and so have limited functionality. Therefore, it is required to transport a number of different mobile electronic devices so as provide the full range of devices required. This is not only cumbersome but can slow down the response times of the emergency response unit.

It is an object of an aspect of the present invention to provide an electronic device that obviates or mitigates one or more of the disadvantages of the prior art.

It is a further object of an aspect of the present invention to provide an electronic device that can be configured so as to provide the functionality of a range of known electronic devices. Such a device finds particular application as a mobile electronic device for use in the field of medicine.

### SUMMARY OF INVENTION

According to a first aspect of the present invention there is provided a configurable electronic device comprising:
a first keyboard section having a first key surface upon which are arranged a plurality of keys and a first surface located opposite to the first key surface;
a second keyboard section having a second key surface upon which are arranged a plurality of keys and a second surface located opposite to the second key surface; and
a first hinge connecting the first and second keyboard sections
   wherein
the first hinge provides a means for rotating the device between a closed position, where first and second key surfaces are adjacently located, and an open position, where the first and second surfaces are adjacently located.

The above arrangement provided a two section electronic device that can be employed as a hand held keyboard, a games console controller or as a remote control device when the device is in the open position. Alternatively when the first and second keyboard sections are arranged in a coplanar manner the device functions as a desktop keyboard.

Preferably the first hinge comprises a double hinge arrangement. Such a hinge allows for the first and second keyboard sections to effectively rotate through 360° about their associated centre of rotation also allowing the centres of rotation to also be rotated relative to each other.

Alternatively, the first hinge comprises a single hinge arrangement. Such a hinge allows only for the first and second keyboard sections to effectively rotate through 360° with respect to the centre of rotation of the hinge.

Preferably the configurable electronic device further comprises a connector so as to provide a means for the device to communicate with a remote screen or computer system.

Preferably the first key surface comprises a plurality of character input keys.

Preferably the second key surface comprises a plurality of command input keys.

Most preferably the configurable electronic device further comprises a screen section, having a display surface and a third surface located opposite to the display surface, and
a second hinge connecting the first keyboard section and the screen sections
   wherein
the second hinge provides a means for rotating the screen section from a first position where first and third surfaces are adjacently located, and an a second position, where the first key surface and the display surface are adjacently located.

The above arrangement provided a three section electronic device that can be employed as a desk top computer, a PDA a mobile phone, a remote control device, a hand held computer or a games console depending on the relative positioning between the first keyboard section, the second keyboard section and the screen section.

Preferably the second hinge comprises a double hinge arrangement.

Optionally the display surface comprises a touch screen display.

Most preferably the configurable electronic device further comprises a protective housing and a third hinge connecting the screen section and the protective housing

wherein
the third hinge provides a means for rotating the protective housing from a first position where the protective housing and the display surface are adjacently located, and an a second position, where the protective housing and the third surface are adjacently located.

The above arrangement provided a four section electronic device that can be employed as a desk top computer, a PDA a mobile phone, a remote control device, a hand held computer or a games console depending on the relative positioning between the first keyboard section, the second keyboard section, the screen section and the protective housing.

Preferably the third hinge comprises a double hinge arrangement.

Optionally the protective housing comprises a plurality of integrated keys. In this embodiment a user may still employ the device even when the protective housing is in the first position since activating the integrated keys provides a means for interacting with the touch screen display.

Most preferably the electronic device further comprises a detachable arm or wrist mount. This embodiment allows the device to be attached to the arm or wrist of a user with only minimal impact upon their manual dexterity.

Preferably the detachable arm or wrist mount comprises a resilient clip suitable for engaging any of the first, second, third, first key or second key surfaces of the device.

Preferably the arm or wrist mount comprises a locating section shaped to engage an arm or wrist of a user.

Optionally the locating section comprises a releasable fastener.

### BRIEF DESCRIPTION OF DRAWINGS

Aspects and advantages of the present invention will become apparent upon reading the following detailed description and upon reference to the following drawings in which:

FIG. 1 presents a plan view of a two section electronic device in accordance with an aspect of the present invention.

FIG. 2 presents a side view of the two section electronic device of FIG. 1 in:
(a) an open, desktop keyboard configuration;
(b) a closed, storage configuration; and
(c) a closed, hand-held keyboard configuration.

FIG. 3 presents a plan view of an alternative embodiment of the invention, namely a three section electronic device.

FIG. 4 presents a side view of the three section electronic device of FIG. 3 in:
(a) an open, desktop computer configuration;
(b) a closed, personal digital assistant (PDA) configuration;
(c) a closed, mobile phone configuration; and
(d) a partially closed, hand-held computer configuration.

FIG. 5 presents the closed, personal digital assistant (PDA) configuration of FIG. 3(b) incorporating an arm mount.

FIG. 6 presents side views of an alternative embodiment of the invention, namely a four section electronic device in:
(a) a personal digital assistant (PDA) configuration with a protective housing in a closed position; and
(b) a personal digital assistant (PDA) configuration with the protective housing in an open position.

FIG. 7 presents the personal digital assistant (PDA) configurations of FIG. 6(a) and (b) incorporating an arm mount.

FIG. 8 presents side views of an alternative embodiment of the four section electronic device in:
(a) a personal digital assistant (PDA) configuration with a keyed protective housing in a closed position; and
(b) a personal digital assistant (PDA) configuration with the keyed protective housing in an open position.

FIG. 9 presents the personal digital assistant (PDA) configurations of FIG. 8(a) and (b) incorporating an arm mount.

### DETAILED DESCRIPTION

To assist clarity of understanding like reference numerals for like features have been adopted, where possible, throughout the various embodiments of the invention described in detail below.

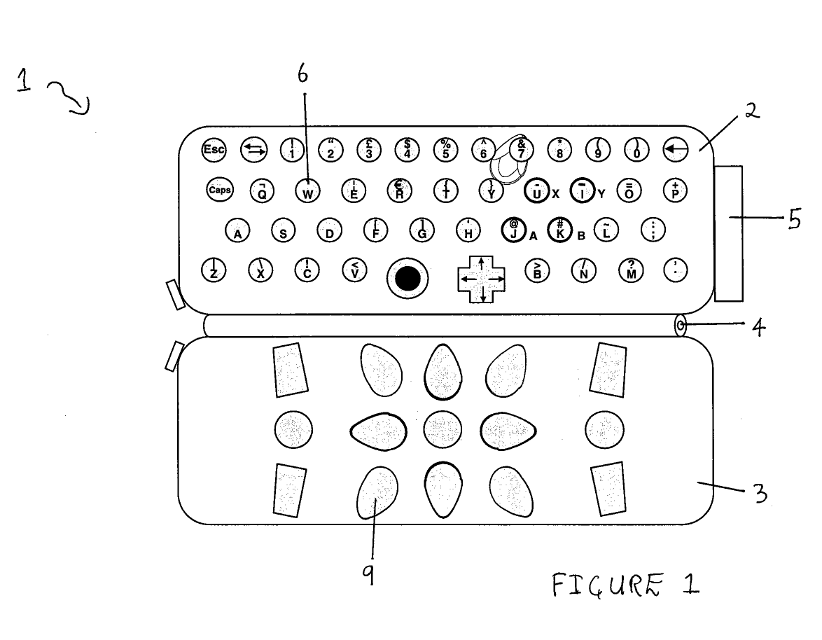

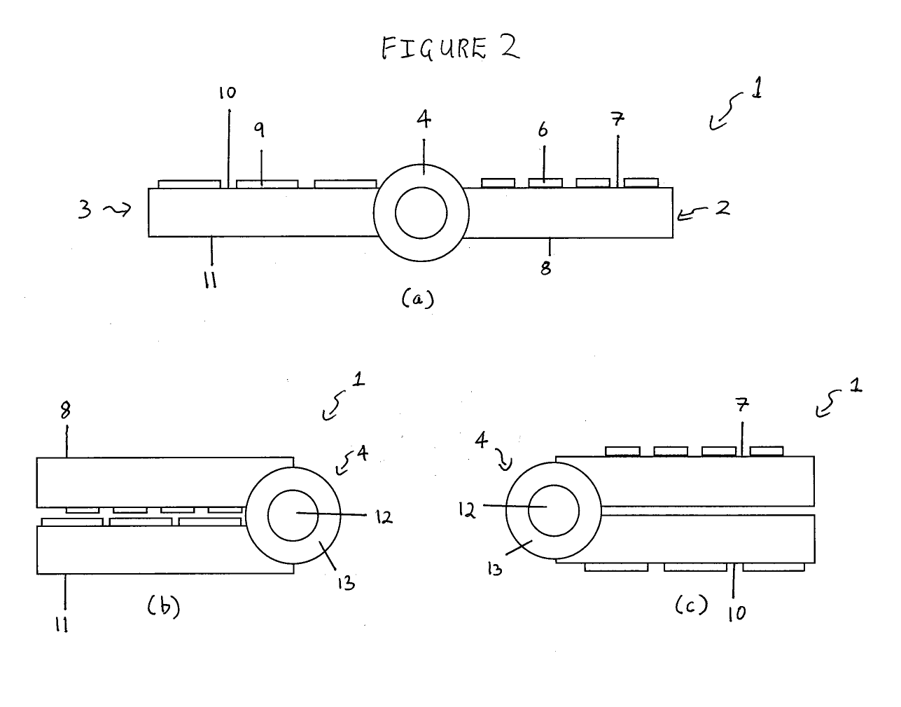

Referring to FIG. 1 a schematic representation of an electronic device 1 in accordance with an aspect of the present invention is presented. The electronic device 1 can be seen to comprise a first 2 and a second keyboard section 3 connected by a hinge 4. A connector 5 allows the electronic device 1 to communicate directly with a remote screen or computer system, as and when required. The connector 5 can be in the form of hard wiring or alternatively via remote access by incorporation of a signal transmitter.

The first keyboard section 2 comprises character input keys 6, namely letter, number and symbol keys arranged in a standard “QWERTY” style layout, located on a first key surface 7. It will be appreciated by the skilled man that other keyboard arrangements to the “QWETRTY” style layout may alternatively be employed. For the clarity of understanding the opposite surface to that upon which the character input keys 6 are located is referred to as the first surface of the device, as indicated by the reference numeral 8.

The second keyboard section 3 comprises the majority of the usual command input keys 9 found on a standard keyboard i.e. shift, control, alt, delete, insert, home, end, page up, page down, mouse control, and function keys located on a second key surface 10. In a similar manner to the first keyboard section 2, the opposite face of the second keyboard section is referred to as the second surface of the device, as indicated by the reference numeral 11.

Importantly, the hinge 4 comprises an inner 12 and an outer cylindrical section 13 that rotate relative to each other so as to effectively provide for 360° of rotation of the second keyboard section 3 relative to the first keyboard section 2, as illustrated in FIG. 2. The hinges 4 are made from plastic or metal materials although any other suitable material that provides for the required degree of movement while allowing the angle between the sections to be maintained, as desired by a user, may alternatively be employed.

In particular, FIG. 2 presents side views of three separate configurations of the two section electronic device 1. In the first configuration, shown in FIG. 2(a), the first 2 and second keyboard sections 3 are substantially coplanar such that the electronic device 1 is in an open, desktop keyboard configuration.

A closed configuration of the electronic device 1 is presented in FIG. 2(b). With respect to FIG. 2(a) the first keyboard section 2 has been rotated though 180° such that the first key surface 7 contacts the second key surface 10. This configuration is particularly suited for storing the electronic device 1 since the risk of physical damage to the character input keys 6 or the command input keys 9 is minimal.

An alternative closed configuration of the electronic device 1 is presented in FIG. 2(c). With respect to FIG. 2(a) the second keyboard section 3 has been rotated though 180° such that the second surface 11 contacts the first surface 8, leaving access to both the character input keys 6 and the command input keys 9. In this configuration the electronic device 1 can be employed as a hand-held keyboard.

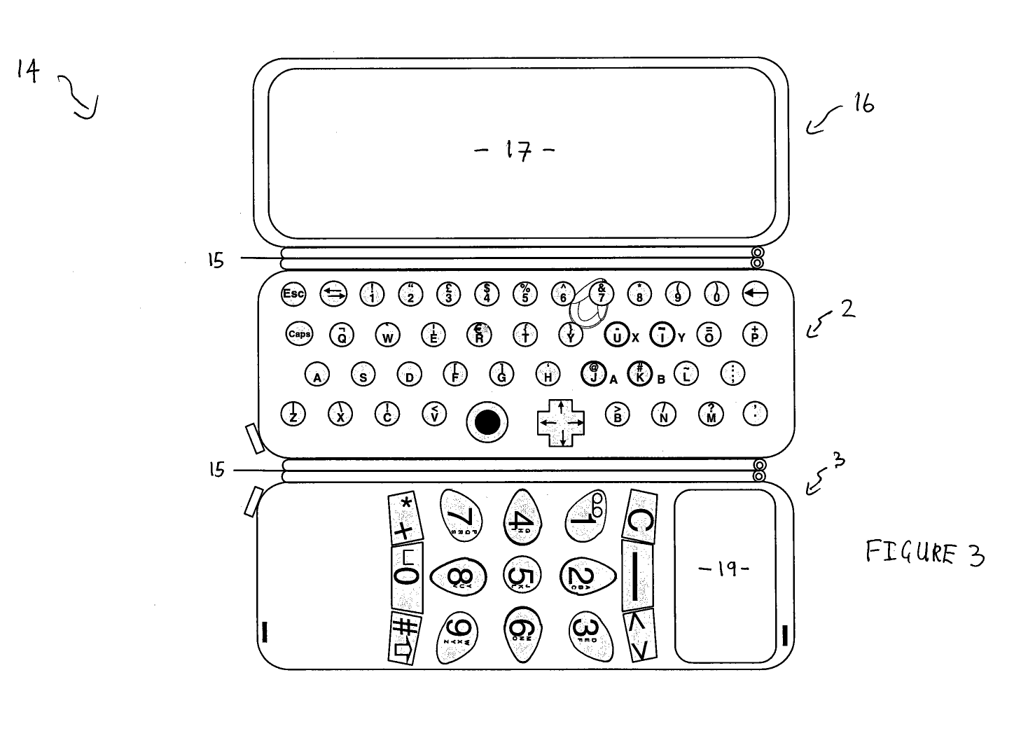

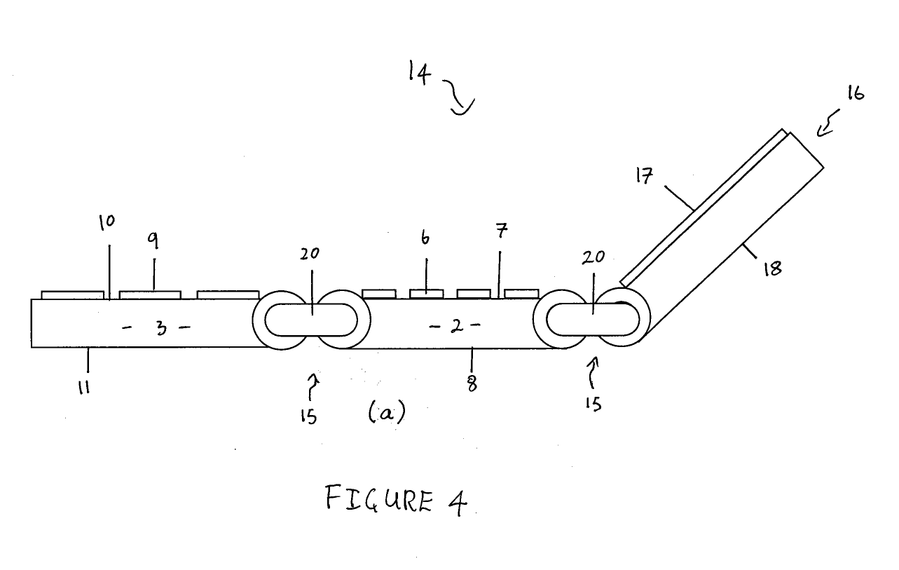

FIG. 3 presents a plan view of an alternative embodiment of the invention, namely a three section electronic device 14. Side views of four operating configurations of the three section electronic device 14 are presented in FIG. 4, as discussed in further detail below.

As with the embodiments presented in FIGS. 1 and 2, the electronic device 14 can be seen to comprise first 2 and second keyboard sections 3, however in this embodiment these sections are connected by a first double hinge 15. In addition a second double hinge 15 connects the first keyboard section 2 to a screen section 16. The screen section comprises a display surface 17 and a third or rear surface of the screen section, located opposite to the display surface 17 as denoted by reference numeral 18.

The first keyboard section 2 again comprises the character input keys 6 while the second keyboard section 3 comprises the command input keys 9. In addition however , the second keyboard section 3 further comprises a small screen 19 which allows the second keyboard section 3 to be employed as a mobile phone, as described if further detail below.

The double hinges 15 of the presently described embodiment comprises two hinges 4, the inner cylindrical sections 12 of which are mechanically attached by a coupling bar 20. Employment of the double hinge 15 therefore provides for the two connected section to effectively rotate through 360° about their associated inner cylindrical sections 12 while the centres of rotation can be also be rotated relative to each other. A clearer understanding of this relative motion will become apparent from the following discussion of the various configurations of the three section electronic device 14, as presented in FIG. 4.

In the first configuration, shown in FIG. 4(a), the first 2 and second keyboard sections 3 are substantially coplanar while the screen section 16 is angled, at approximately 45° to the first keyboard section 2, such that the display surface 17 is towards the normal operation position of a user. In this configuration the electronic device 14 is in an open, desktop computer configuration.

A closed configuration of the electronic device 14 is presented in FIG. 4(b). With respect to FIG. 4(a) the first keyboard section 2 has been rotated though 180° such that the first key surface 7 contacts the second key surface 10 thus providing physical protection for the character input keys 6 and the command input keys 9. The screen section 16 has also been rotated through 225° such that the third or rear surface 18 contacts the first surface of the first keyboard section 8. In this configuration the display surface 17 remains free for use and thus the electronic device 14 can be employed as personal digital assistant (PDA).

An alternative closed configuration of the electronic device 14 is presented in FIG. 4(c). With respect to FIG. 4(a) the first keyboard section 2 has been rotated though 180° such that the first surface of the first keyboard section 8 contacts the second surface of the second keyboard section 11. The screen section 16 has also been rotated through 135° such that the display surface of the screen section 17 contacts the first key surface 7, thus providing physical protection for the character input keys 6. In this configuration the second key surface 10 remains free for use and so the electronic device 14 can be employed as a mobile phone.

A partially closed configuration of the electronic device 14 is now described with reference to FIG. 4(d). With respect to FIG. 4(a) the second keyboard section 3 has been rotated though 180° such that the second surface 11 contacts the first surface 8. The screen section 16 remains angled at approximately 45° to the first keyboard section 2. In this configuration the electronic device 14 can be employed by a user as hand-held computer.

In the above described embodiments it may be beneficial for the user for the display surface 17 to operate in either a portrait format (for the PDA of FIG. 4(b)) or a landscape format (for the desktop and hand-held computer configurations of FIG. 4(a) and FIG. 4(b)). Therefore, the electronic device 14 incorporates a switching facility such that the display surface 17 may be quickly and simply switched between a landscape and a portrait mode of operation, as desired by the user.

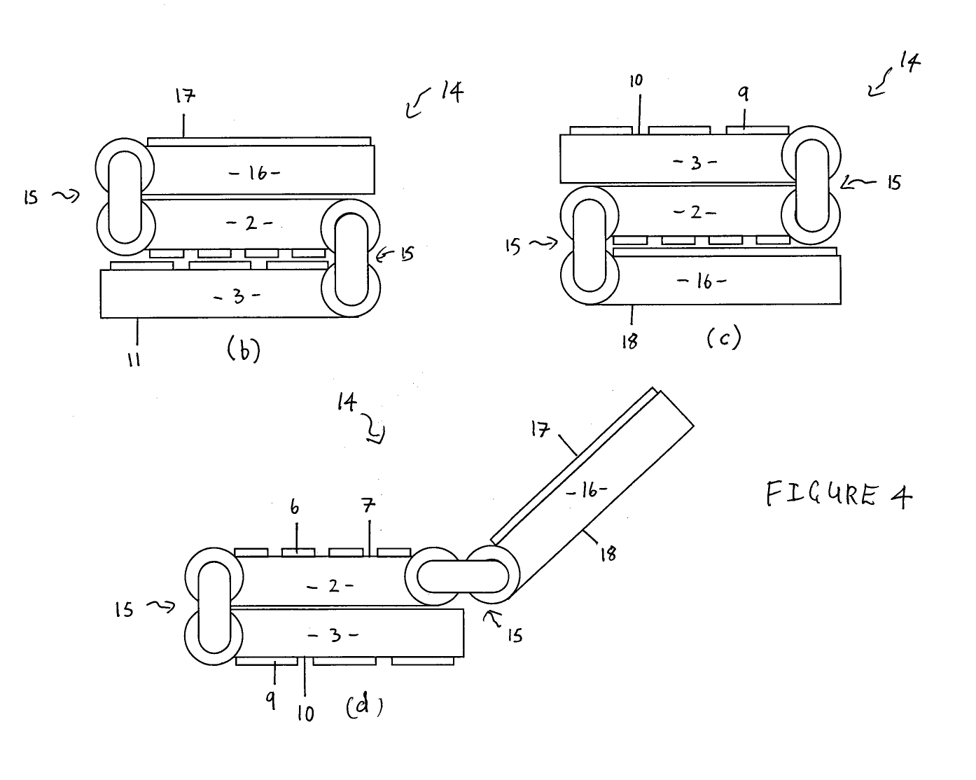

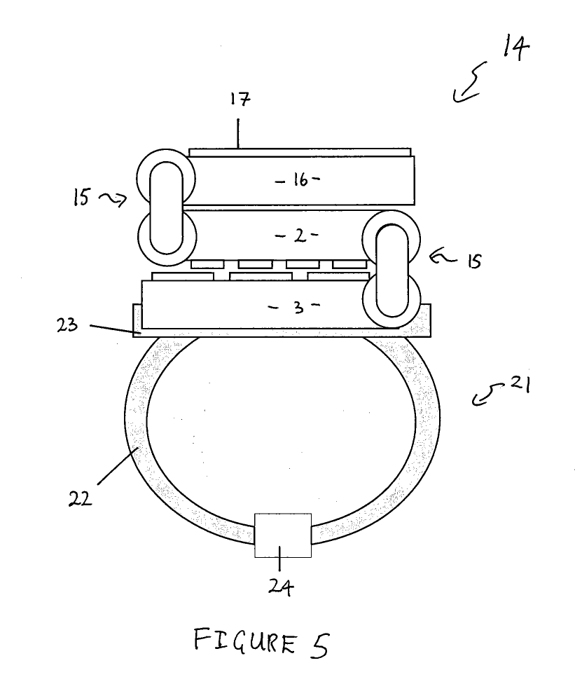

A yet further alternative embodiment of the three section electronic device 14 is presented in FIG. 5. Here the three section electronic device 14 is in the PDA configuration of FIG. 4(b) but now incorporates an arm or wrist mount 21.

The arm or wrist mount 21 comprises a substantially elliptical section 22 on one side of which is located a mechanically resilient clip 23, having a substantially U-shaped cross section, opposite to which is located a fastener 24. The cross section of the clip is chosen such that it readily mates with, and secures to, a free surface of the electronic device 14. In the presently described embodiment the arm or wrist mount 21 is clipped onto the second surface 11. However, the arm or wrist mount 21 may alternatively clip onto the third surface 18 which is free within the mobile phone configuration presented in FIG. 4(c).

When required to be deployed the fastener 24 is simply undone so as to allow a user to position the elliptical section 22 about their forearm or wrist, as appropriate. On securing the fastener 24 the electronic device 14 is secured in position while allowing a user freedom to use both hands with only minimal impact to their manual dexterity. This functionality is of obvious significant benefit for emergency medical units.

FIGS. 6 through 9 present various embodiments of a four section electronic device 25. Each of these embodiments is based on the PDA configuration of the three section electronic device 14 described in detail above with respect to FIG. 4(b). However each of these embodiments differ in that they further comprise a protective housing 26 attached to the screen section 16 by a third double hinge 15b. It can be seen that the third hinge 15b is of a smaller size than those previously described. However, this hinge 15b operates in an identical manner and so provides the same flexibility for positioning the protective housing 26 relative to the screen section 16.

In FIG. 6(a) the protective housing 26 has been rotated so as to provide physical protection to the display surface 17. Alternatively, the protective housing 26 may be rotated through 360° so that it can be located between the third surface 18 and the first surface of first keyboard section 8, as shown in FIG. 6(b). In this way the electronic device 25 operates as a PDA than can be simply and quickly moved between a closed position, see FIG. 6(a), and an open position, see FIG. 6(b).

It will be appreciated by those skilled in the art that the open position does not necessarily require the protective housing 26 to be located between the third surface 18 and the first surface 8. An alterative open position may be employed where the protective housing 26 simply depends from the third hinge 15b.

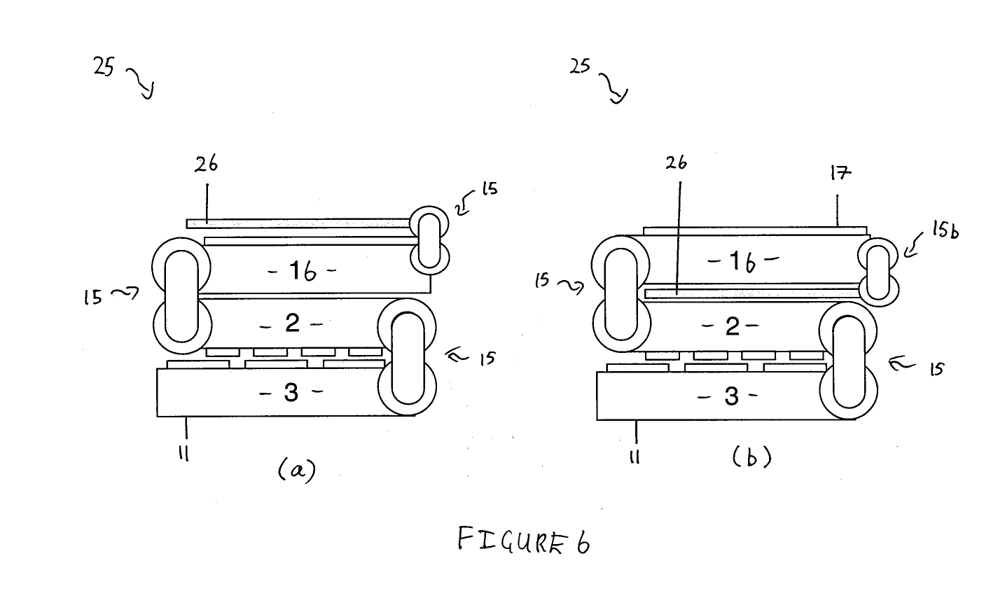

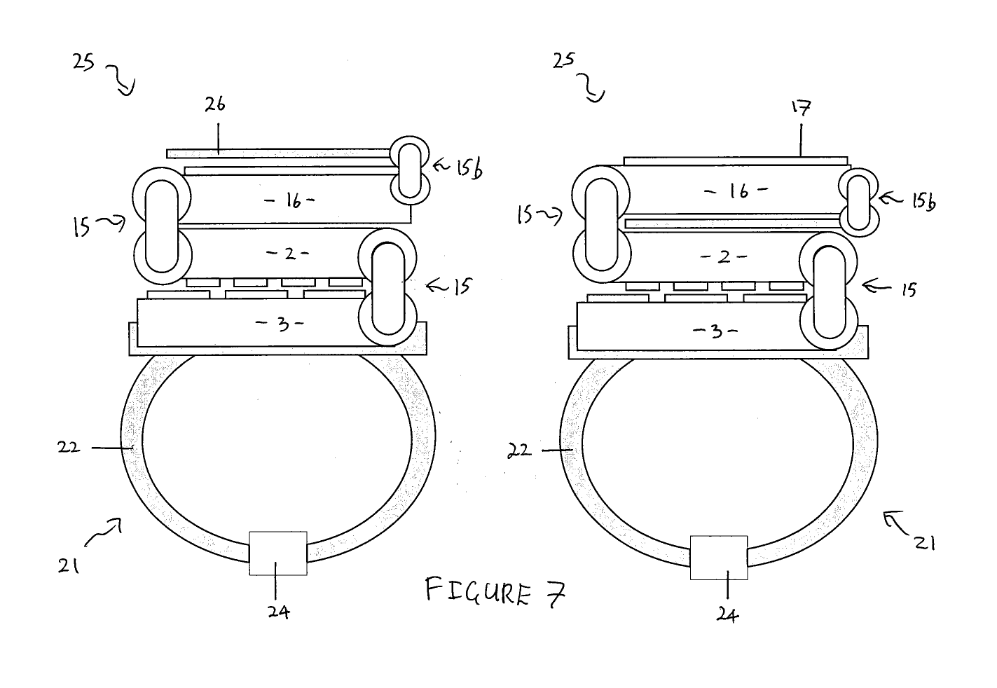

The flexible nature of the electronic device 25 is further demonstrated with reference to FIG. 7. In particular, FIGS. 7(a) and (b) present the personal digital assistant (PDA) configurations of FIG. 6(a) and (b), respectively, incorporating the arm or wrist mount 21.

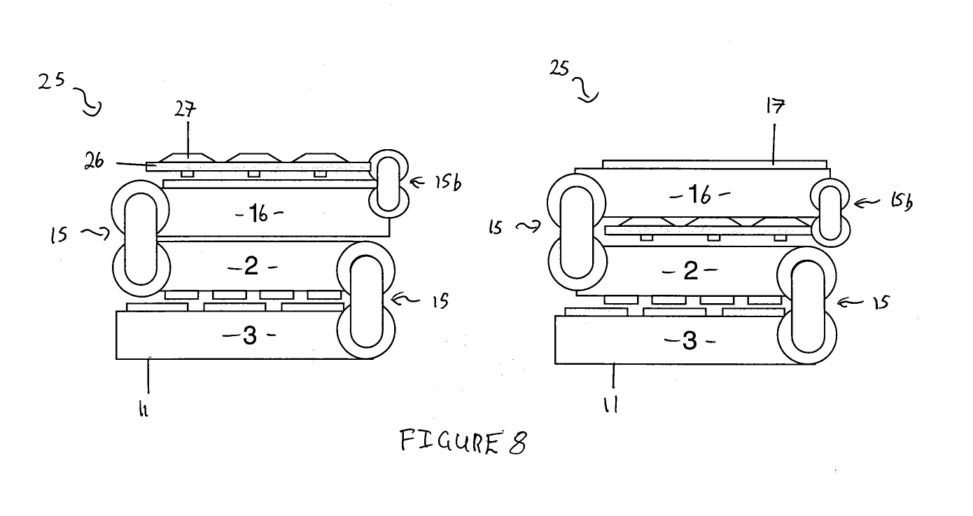

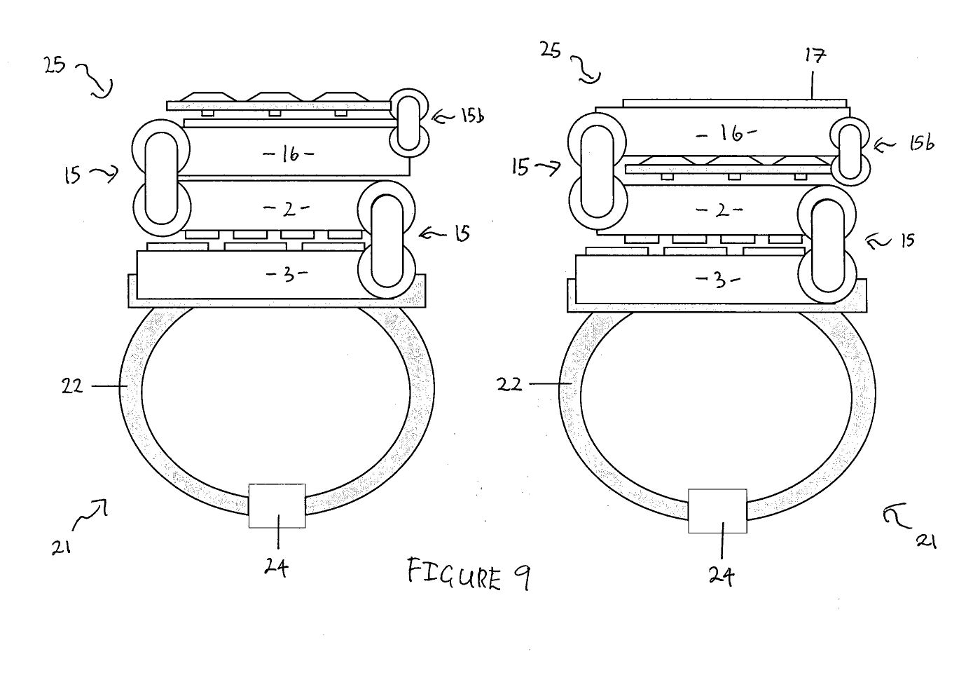

In the embodiments of the electronic device 25b shown in FIGS. 8 and 9 the protective housing 26b has been adapted such that it incorporates a plurality of integrated keys 27. In a similar manner to FIGS. 6 and 7, FIGS. 8 and 9 present the electronic device 25b operating as a PDA in a closed and an open configuration, in the absence and presence of the arm or wrist mount 21, respectively. When in the closed position of FIGS. 8(a) or 9(a) the integrated keys 27 make contact with the display surface 17 when depressed by a user.

The electronic device 25b is intended to employ a touch screen display surface 17. Thus even when in the closed configuration of FIGS. 8(a) and 9(a) data can still be entered into the device by activation of the integrated keys 27. Such a configuration finds particular application in an environment where the user is required to suppress the light generated by the display surface 17. An example of such an application would be for emergency response units operating within a battlefield environment.

The above described invention provides a configurable electronic device that exhibits significantly increased functionality when compared with those devices known from the prior art. It will be appreciated that the described embodiments are by way of example only and that alternative configuration may alternatively be achieved. For example, the closed configuration of FIG. 2a) may alternatively be employed as a games console controller or as a remote control for a secondary electronic device. Furthermore, if the second keyboard section 3 employed within the described three section electronic device 14 was employed within the two section electronic device 1, then the closed configuration of FIG. 2(a) may be employed as a mobile phone.

The above described embodiments provide an electronic device that exhibits the functionality of a range of known mobile electronic devices e.g. a notebook computer, a mobile telephone, a palm top computer, a communicator, a personal digital assistant (PDAs), an electronic organiser, a games console, a remote control, and the like. The design of the electronic device allows for the rapid and simple transition between the variously described configurations.

A further advantage of the described device is that for many of the configurations, physical protection can be provided for the keys and/or the associated screens.

It is expected that the device will provide particular application for the use by mobile emergency services, however the invention is not intended to be limited to such use.

The foregoing description of the invention has been presented for purposes of illustration and description and is not intended to be exhaustive or to limit the invention to the precise form disclosed. The described embodiments were chosen and described in order to best explain the principles of the invention and its practical application to thereby enable others skilled in the art to best utilise the invention in various embodiments and with various modifications as are suited to the particular use contemplated. Therefore, further modifications or improvements may be incorporated without departing from the scope of the invention as herein intended.

What is claimed is:

1) A configurable electronic device comprising:
a first keyboard section having a first key surface upon which are arranged a plurality of keys and a first surface located opposite to the first key surface;
a second keyboard section having a second key surface upon which are arranged a plurality of keys and a second surface located opposite to the second key surface; and
a first hinge connecting the first and second keyboard sections
wherein
the first hinge provides a means for rotating the device between a closed position, where first and second key surfaces are adjacently located, and an open position, where the first and second surfaces are adjacently located.

2) A configurable electronic device as claimed in claim 1 wherein the first hinge comprises a double hinge arrangement.

3) A configurable electronic device as claimed in claim 1 wherein the first hinge comprises a single hinge arrangement.

4) A configurable electronic device as claimed in claim 1 wherein the device further comprises a connector so as to provide a means for the device to communicate with a remote screen or computer system.

5) A configurable electronic device as claimed in claim 1 wherein the first key surface comprises a plurality of character input keys.

6) A configurable electronic device as claimed in claim 1 wherein the second key surface comprises a plurality of command input keys.

7) A configurable electronic device as claimed in claim 1 wherein the device further comprises a screen section, having a display surface and a third surface located opposite to the display surface, and a second hinge connecting the first keyboard section and the screen sections wherein the second hinge provides a means for rotating the screen section from a first position where first and third surfaces are adjacently located, and an a second position, where the first key surface and the display surface are adjacently located.

8) A configurable electronic device as claimed in claim 7 wherein the second hinge comprises a double hinge arrangement.

9) A configurable electronic device as claimed in claim 7 wherein the display surface comprises a touch screen display.

10) A configurable electronic device as claimed in claim 7 wherein the configurable electronic device further comprises a protective housing and a third hinge connecting the screen section and the protective housing wherein the third hinge provides a means for rotating the protective housing from a first position where the protective housing and the display surface are adjacently located, and an a second position, where the protective housing and the third surface are adjacently located.

11) A configurable electronic device as claimed in claim 10 wherein the third hinge comprises a double hinge arrangement.

12) A configurable electronic device as claimed in claim 10 wherein the protective housing comprises a plurality of integrated keys.

13) A configurable electronic device as claimed in claim 10 wherein the device further comprises a detachable arm or wrist mount.

14) A configurable electronic device as claimed in claim 13 wherein the detachable arm or wrist mount comprises a resilient clip suitable for engaging any of the first, second, third, first key or second key surfaces of the device.

15) A configurable electronic device as claimed in claim 13 wherein the arm or wrist mount comprises a locating section shaped to engage an arm or wrist of a user.

16) A configurable electronic device as claimed in claim 15 wherein the locating section comprises a releasable fastener.
